(19) United States
(12) Patent Application Publication
(10) Pub. No.: US 2009/0078306 A1
(43) Pub. Date: Mar. 26, 2009

(54) Apparatus and methods for retaining a plurality of elongated photovoltaic modules

(75) Inventors: Andrew Nagengast, Sunnyvale, CA (US); Thomas Brezoczky, Los Gatos, CA (US)

Correspondence Address: Jones & Smith, LLP;Attn: Randy Smith, 2777 Allen Parkway, Suite 800, Houston, TX, 77019, US

(73) Assignee: Solyndra, Inc., Fremont, CA (US)

(21) Appl. No.: 12/069,813

(22) Filed: Feb. 13, 2008

Related U.S. Application Data
(60) Provisional application No. 61/001,605, filed on Nov. 2, 2007.
(60) Provisional application No. 60/994,696, filed on Sep. 21, 2007.

(51) Int. Cl. H01L 31/048; H01L 31/042; B29C 39/00

(52) U.S. Cl. 136/251; 136/244; 264/241

(57) ABSTRACT

In some embodiments, an apparatus for assisting in retaining at least two elongated photovoltaic modules includes a carrier having at least first and second adjacent receptacles. Each receptacle is engageable with at least one elongated photovoltaic module and the carrier is moveable between the first and second receptacles.

This application claims priority to U.S. provisional application Ser. Nos. 61/001,605 filed on Nov. 2, 2007 and entitled “Apparatus and Methods for Sealing an Electrical Connection to at Least one Elongated Photovoltaic Module” and 60/994,696 filed on Sep. 21, 2007 and entitled “Apparatus and Methods for Retaining a Plurality of Elongated Photovoltaic Modules”, both of which are hereby incorporated by reference herein in their entireties.

### BACKGROUND

This patent relates to photovoltaic energy absorption/collection technology, and, in particular, apparatus and methods for retaining a plurality of elongated photovoltaic modules.

Various known photovoltaic energy absorption/collection devices, such as solar panels, include an array of photovoltaic modules arranged side-by-side in a box-like housing having a length and width disproportionately larger than its thickness. To collect or absorb a useful amount of light, these structures are typically very large and heavy. As a result of their size, weight and cumbersome shape, these devices are often very difficult to handle, transport and install at their final destination.

It should be understood that the above-described examples, features and/or disadvantages are provided for illustrative purposes only and are not intended to limit the scope or subject matter of the claims of this patent application or any patent or patent application claiming priority hereto. Thus, none of the appended claims or claims of any related application or patent should be limited by the above discussion or construed to address, include or exclude the cited examples, features and/or disadvantages, (except as may be expressly recited in any particular claims and only with respect thereto).

### BRIEF DESCRIPTION OF THE DRAWINGS

The following figures are part of the present specification, included for background purposes or to demonstrate certain aspects of embodiments of the present disclosure and referenced in the detailed description herein.

FIG. 1 is a perspective view of an embodiment of a carrier assembly made in accordance with the present disclosure and shown holding a plurality of elongated photovoltaic modules;

FIG. 2 is a cross-sectional view of an example elongated photovoltaic module show in FIG. 1 taken along lines 2-2;

FIG. 3 is a cross-sectional view of an exemplary receptacle of one of the carriers of the carrier assembly shown in FIG. 1 taken along lines 3-3;

FIG. 4 is a side view of an embodiment of a carrier in accordance with the present disclosure shown in a partially folded state;

FIG. 5 is an exploded view of a portion of the exemplary carrier shown in FIG. 4;

FIG. 6 is a perspective view of another embodiment of a carrier assembly made in accordance with the present disclosure and shown holding a plurality of photovoltaic modules;

FIG. 7 is a top view of yet another embodiment of a carrier assembly made in accordance with the present disclosure and shown holding a plurality of photovoltaic modules;

FIG. 8 is a front view of the carrier assembly shown in FIG. 7;

FIG. 9 is an isolated view of an embodiment of a connector made in accordance with the present disclosure;

FIG. 10 is an isolated view of another embodiment of a connector made in accordance with the present disclosure; and

FIG. 11 is an isolated view of yet another embodiment of a connector made in accordance with the present disclosure.

### DETAILED DESCRIPTION

Characteristics and advantages of the present disclosure and additional features and benefits will be readily apparent to those skilled in the art upon consideration of the following detailed description and referring to the accompanying figures. It should be understood that the description herein and appended drawings are of various exemplary embodiments and are not intended to limit the appended claims or the claims of any patent or patent application claiming priority hereto. On the contrary, the intention is to cover all modifications, equivalents and alternatives falling within the spirit and scope of the claims. Many changes may be made to the particular embodiments and details disclosed herein without departing from such spirit and scope.

In the description below and appended figures, like or identical reference numerals are used to identify common or similar elements. The figures are not necessarily to scale and certain features and certain views of the figures may be shown exaggerated in scale or in schematic in the interest of clarity and conciseness. It should also be noted that reference herein and in the appended claims to components and aspects in a singular tense does not necessarily limit the present disclosure or claims to only one such component or aspect, but should be interpreted generally to mean one or more, as may be suitable and desirable in each particular instance.

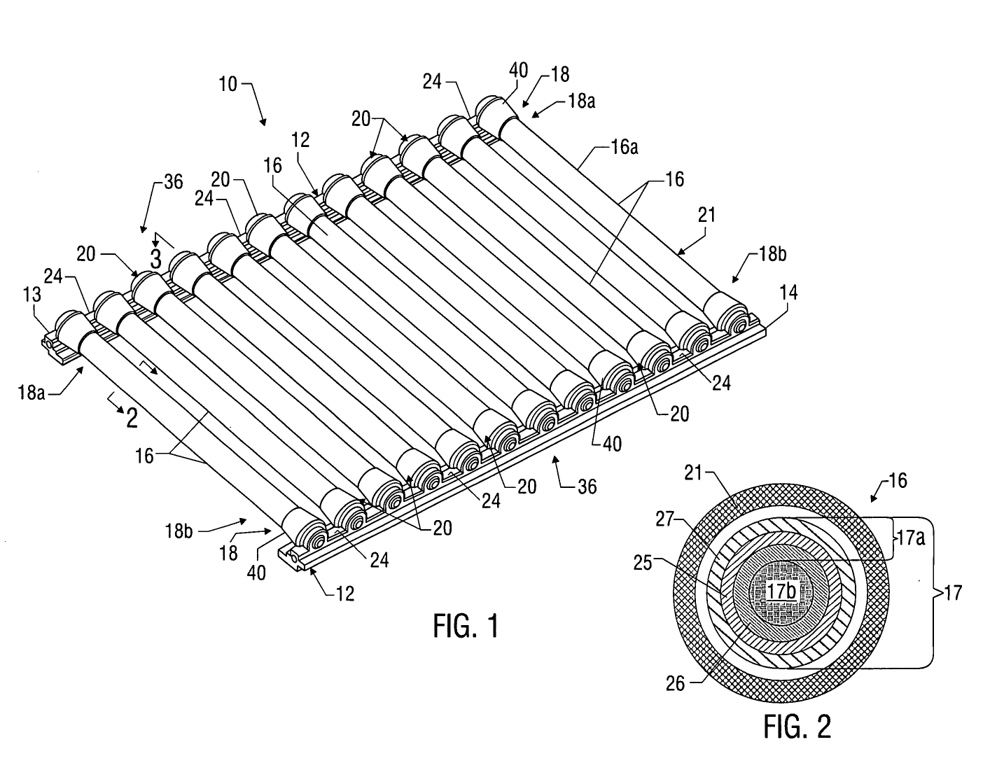

Referring initially to FIG. 1, a carrier assembly 10 made in accordance with an embodiment of the present disclosure includes at least one carrier 12 shown holding at least two elongated photovoltaic cells, or modules, 16. Each carrier 12 includes at least two adjacent receptacles 20 and is moveable therebetween. As used herein, the term “movable” and variations thereof means flexible, bendable, foldable, hinged, or the like, sufficient to enable the position or relationship of adjacent receptacles to be changed relative to one another. Each receptacle 20 is capable of firmly engaging an end 18 of at least one elongated photovoltaic module 16. When the exemplary carrier assembly 10 includes carriers 12 engaged with opposite ends 18 of at least two elongated photovoltaic modules 16, such as the embodiment of FIG. 1, the carriers 12 form a framework for holding the elongated photovoltaic modules 16 and are concurrently movable between respective adjacent engaged elongated photovoltaic modules 16.

The carrier assembly 10 of the present disclosure may be used with any suitable elongated photovoltaic modules 16. Thus, the present disclosure and appended claims are not limited by the elongated photovoltaic modules 16 (except as may be expressly recited in any particular claims and only with respect thereto). Further, different types and configurations of elongated photovoltaic modules 16 may be used in the same carrier assembly 10.

For purposes of this discussion, an elongated photovoltaic module 16 is characterized by having a longitudinal dimension and a width dimension. In some embodiments, for example, the longitudinal dimension of the elongated photovoltaic module 16 (or simply the “module 16”) exceeds the width dimension by at least a factor of 4, at least a factor of 5, or at least a factor of 6. In some embodiments, the longitudinal dimension of the module 16 is 10 centimeters (cm) or greater, 20 cm or greater, or 100 cm or greater. In some embodiments, the width dimension of the module 16 is a diameter of 500 mm or more, 1 cm or more, 2 cm or more, 5 cm or more, or 10 cm or more. However, the present disclosure and appended claims are not limited to any such examples (except as may be expressly recited in any particular claims and only with respect thereto).

In the example of FIG. 1, each illustrated module 16 has a generally cylindrical overall shape and a generally circular cross-sectional shape to capture light from any direction. For other examples, the modules 16 may have a cylindric-like shape, bifacial or omnifacial configuration, or otherwise be designed to capture light on planes both facing and not facing the initial light source. An example omnifacial topology of a module 16 may include a bifacial configuration where both its top and bottom planes accept light and produce electric power in response to that light. Another example omnifacial topology may collect reflected light on the back and/or sides of the module 16 and light striking the module 16 from any direction other than the planar orientation of the carrier assembly 10. However, the modules 16 need not be capable of having an omnifacial topology (e.g. capable of absorbing light from more than one direction). The modules 16 may thus have any suitable cross-sectional shape, such as square, rectangular, elliptical, polygonal, or have a varying cross-sectional shape, and any desired overall shape and configuration.

The modules 16 may likewise have any suitable construction. Each illustrated module 16 of FIG. 1 includes an active photovoltaic device 17 (FIG. 2) and an outer protective structure 21 at least partially surrounding the photovoltaic device 17. The outer protective structure 21 may, for example, be a shell that defines an inner volume within which the photovoltaic device 17 is contained, such as to protect the photovoltaic device 17, allow light energy to pass from outside the module 16 to the photovoltaic device 17, other suitable purpose or a combination thereof. In many embodiments, the outer protective structure 21 may be constructed of material that allows substantial light energy to pass through it, such as plastics, glasses and transparent ceramics. An example outer protective structure 21 is a tubular glass casing.

Referring still to the example of FIG. 2, the active photovoltaic device 17 of the illustrated module 16 includes at least one photovoltaic cell 17a, operable to convert light energy to electric energy, disposed upon at least one substrate 17b. The substrate 17b may have any suitable form. For example, the substrate may be elongated or non-elongated; rigid, partially rigid or non-rigid; solid, hollow, or a combination thereof; closed at either or both ends, or open at both ends. An example substrate 17b is a solid and rigid elongated glass rod.

Rigidity of a material can be measured using several different metrics including, but not limited to, Young's modulus. In solid mechanics, Young's Modulus (E) (also known as the Young Modulus, modulus of elasticity, elastic modulus or tensile modulus) is a measure of the stiffness of a given material. It is defined as the ratio, for small strains, of the rate of change of stress with strain, which can be experimentally determined from the slope of a stress-strain curve created during tensile tests conducted on a sample of the material. Young's modulus for various materials is given in the following table.

| | Young's | |
|---|---|---|
| | modulus (E) | Young's modulus (E) in |
| Material | in GPa | lbf/in² (psi) |
| Rubber (small strain) | 0.01-0.1 | 1,500-15,000 |
| Low density polyethylene | 0.2 | 30,000 |
| Polypropylene | 1.5-2 | 217,000-290,000 |
| Polyethylene terephthalate | 2-2.5 | 290,000-360,000 |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced plastic | 150 | 21,800,000 |
| (unidirectional, along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments, a component or item (e.g. substrate 17b of FIG. 2) is deemed to be rigid when it is constructed of a material that has a Young's modulus of 20 GPa or greater, 30 GPa or greater, 40 GPa or greater, 50 GPa or greater, 60 GPa or greater or 70 GPa or greater. In various embodiments, a material is deemed to be rigid when the Young's modulus for the material is a constant over a range of strains. Such materials are sometimes referred to as “linear” and are said to obey Hooke's law. Thus, in some embodiments, the substrate is made out of a linear material that obeys Hooke's law. Examples of such linear materials include, but are not limited to, steel, carbon fiber, and glass. Examples of non-linear materials are rubber and soil (except at very low strains). In other embodiments, a material is deemed rigid when the combination of material and dimensions are such that the material does not substantially deform when subjected to the effects of a force of 9.8 meters/sec.².

While some embodiments of suitable substrates 17b have rigid cylindrical shapes, such as solid rods, all or a portion of the elongated substrate may have a cross-section bounded by any desirable shape. The bounding shape of the substrate 17b may be circular, ovoid or another shape characterized by one or more smooth curved surfaces, or any splice of smooth curved surfaces; have a linear nature, including triangular, rectangular, pentangular, hexagonal or any other number of linear segmented surfaces; be an n-gon, where n is 3, 5 or more; include at least one arcuate edge; include any combination of linear surfaces, arcuate surfaces or curved surfaces.

In some embodiments, a first portion of the substrate 17b is characterized by a first cross-sectional shape and a second portion of the substrate 17b is characterized by a second cross-sectional shape, where the first and second cross-sectional shapes are the same or different. For some examples, at least ten, twenty, thirty, forty, fifty, sixty, seventy, eighty, ninety or one-hundred percent of the length of the substrate 17b may be characterized by the first cross-sectional shape. In some embodiments, the first cross-sectional shape of the substrate 17b is planar (e.g., has no arcuate side) and the second cross-sectional shape has at least one arcuate side.

Referring back to the example of FIG. 2, the photovoltaic cell(s) 17a may likewise have any suitable form. In some embodiments, the photovoltaic cell 17a includes multiple layers of material circumferentially coating the substrate 17b. For example, a photovoltaic layer 25 may be sandwiched between an underlying layer of conducting material 26 and an outer layer of transparent conducting material 27. An example conducting material 26 is a back electrode (not shown) disposed on the substrate 17b.

The photovoltaic layer 25 may be disposed on the conducting material layer 26 and operable to produce an electric potential and electric current. The photovoltaic layer 25 may include any material or combinations of materials that produce a photovoltaic effect. For example, the photovoltaic layer 25 may include layers of differing charged semiconductor materials, where one overlays the other. Semiconductor materials, when used, may be formed, for example, as a hetero-junction semiconductor or semiconductor junction formed from a common substance with opposing layers having oppositely-doped characteristics. Any other suitable photovoltaic material(s) may be used, such as photoelectrochemical cells, polymer solar cells, organic-based photovoltaic materials, nanocrystal solar cells, polymers with nano particles mixed together to make a single multispectrum layer.

An example transparent conducting material 27 is a transparent conductive oxide (not shown) disposed on the photovoltaic layer 25. For another example, the transparent conducting material 27 may be a “net” or other configuration of otherwise non-transparent conductive material placed over the photovoltaic material, and may not cover the entire photovoltaic layer 25.

If desired, the annular volume between the photovoltaic device 17 and the outer protective structure 21 may include material to assist in protecting the photovoltaic device 17, a non-reactive gas or other suitable substance(s).

In some embodiments, the module 16 has an integral formation of a plurality of photovoltaic solar cells 17a coupled together electrically over a monolithic substrate 17b in an elongated structure. For instance, each photovoltaic cell 17a in a module may occupy a portion of an underlying substrate 17b common to the entire photovoltaic module 16 and the cells 17a electrically coupled together in series or parallel. In other embodiments, the module 16 may have a single photovoltaic cell 17a disposed on a substrate 17b. In yet other examples, the module 16 may include a plurality of photovoltaic cells 17a each made on their own individual substrates 17b and linked together electrically. The individual cells 17a may be coupled either serially, in parallel or a combination thereof. For example a photovoltaic module 16 may have 1, 2, 3, 4, 5 or more, 20 or more, or 100 or more such photovoltaic cells 17a.

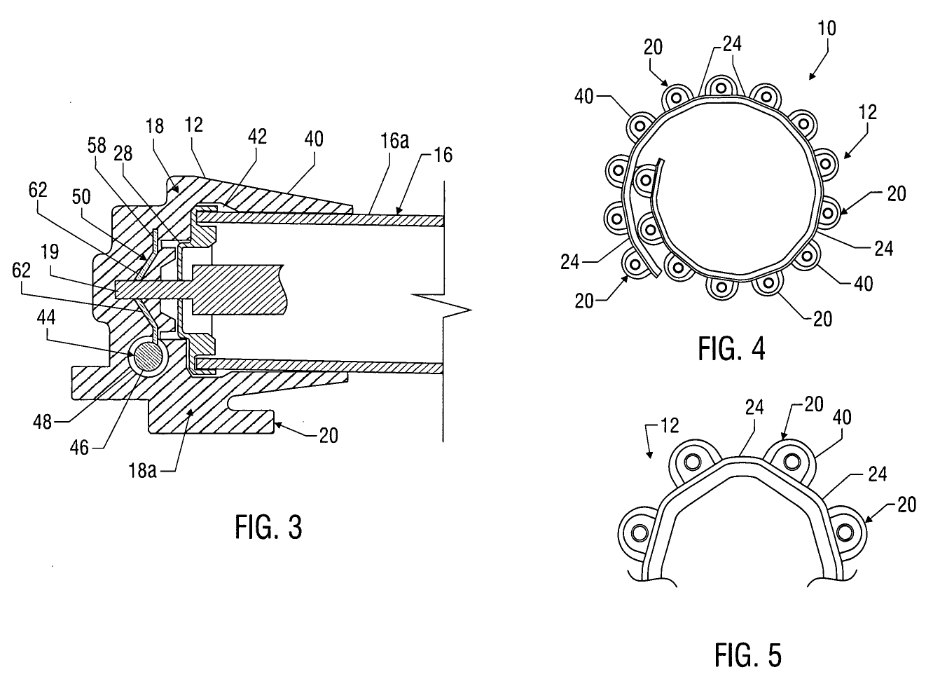

Referring back to the example of FIG. 1, each illustrated module 16 is sealed and includes an end cap 28 (e.g. FIG. 3) and at least one electrical output contact 19 at each end 18. The output contact 19 provides the electricity that is generated by the module 16. The end cap 28 provides a water-tight seal around the end of the module 16 and electrically isolates the output contact 19. In the particular arrangement of FIG. 1, the output contacts 19 at the first ends 18a (e.g. FIG. 3) of the modules 16 are anodes, while the output contacts 19 at the second ends 18b of modules 16 are cathodes, but any other arrangement may be employed. Each module 16 may include only a single output contact 19 or multiple output contacts 19 at any desired location (e.g. intermediate to its ends).

Additional description and details of the components, construction and operation of various examples of elongated photovoltaic modules and other components that may potentially be used with the carrier assembly 10 of the present disclosure may be found in U.S. patent application Ser. Nos. 11/378,835, 60/859,213, 60/859,212, 60/859,188, 60/859,033, 60/859,215, 60/861,162, 60/901,517, 61/001,605, 60/994,696 and all U.S. patent applications and patents claiming priority thereto, all of which have a common assignee as the present application and are hereby incorporated by reference herein in their entireties. Again, the present disclosure and appended claims are not limited by the structure, components, operation or other aspects of the photovoltaic modules (except as may be expressly recited in any particular claims and only with respect thereto).

The exemplary modules 16 of FIG. 1 are engaged in the carrier assembly 10 in a generally fixed or rigid relationship and are, thus, load bearing elements. In other configurations, one or more modules 16 may be movable. For example, the modules 16 may be engaged in the carrier assembly 10 so that they may be individually or collectively swiveled or tilted at angles relative to the assembly 10, such as to track the movement of the sun.

In accordance with the present disclosure, the carrier 12 may have any suitable form, construction and configuration. Further, the carrier 12 may be moveable between adjacent receptacles 20 in any desired manner. For example, the carrier 12 may be at least partially constructed of flexible material so that it is moveable, such as by flexing or bending, between adjacent receptacles 20. Some examples of such materials include rubber, shape memory composites and various plastics and plastic-based composites. In some instances, the carrier 12 may essentially string together the receptacles 20 so that it is loose or relaxed between adjacent receptacles 20, similar to a “rope ladder” or Christmas tree light structure.

If desired, the material composition of at least part of the carrier 12 may be selected for one or more additional purpose, such as to facilitate engagement with the modules 16, provide electrical insulation, assist in reducing stress applied to the modules 16, provide strength and durability, provide rigidity at portions of the carrier 12 that are not moveable, or any other desired purpose. In the embodiment of FIG. 1, the carrier 12 is constructed of a non-electrically conductive material, such as rubber, and formed by a molding or extrusion process. The illustrated carrier 12 includes a bridge portion 24 extending between each adjacent receptacle 20 and which is sufficiently flexible to bend as desired. In FIG. 4, the exemplary carrier 12 is shown bent at various bridge portions 24, and in FIG. 5, the (roughly estimated) deformation of the illustrated bridge portions 24 is shown. In other examples, the carrier 12 may be only partially constructed of a non-electrically conductive, bendable material, or only certain bridge portions 24 may be bendable or otherwise moveable. The carrier 12 may thus be movable between its original shape (e.g. FIG. 1) and one or more desired folded, coiled, or other overall different shape by bending at the appropriate bridge portions 24.

The amount of force, pressure or other action (if any) that may be required to cause the movement of the carrier 12 between receptacles 20 will likely depend upon the material composition and dimensions of the carrier(s) 12 and other design features of the carrier assembly 10, as well as the particular desired movability of the carrier 12. In some embodiments, the bridge portion 24 may be bendable when merely subjected to the force of gravity.

In various embodiments, a move mechanism (not shown) may be included between receptacles 20 on the carrier 12 to allow movement of the carrier 12 between receptacles 20. Move mechanisms are referred to herein as “hinged portions”, which includes any component(s) or device(s) associated with a carrier 12, or configuration of one or more component of a carrier 12 that allows movement of one receptacle 20 of the carrier 12 relative to an adjacent receptacle 20 of the carrier 12, other than by only the bending or flexing of the carrier 12. Move mechanisms may take any suitable form. In some embodiments, the move mechanisms may be integrally formed as part of the carrier 12 or connected with the carrier 12 in any desired manner. Some example move mechanisms that may be disposed on the carrier 12 between adjacent receptacles 20 are joints and hinges (not shown).

The ability to move or fold the carrier 12 between receptacles 20 may be useful for any desired purpose, such as ease of storage, transportation, delivery and/or handling of individual carriers 12 or a carrier assembly 10 with engaged modules 16. For example, in some embodiments, the carrier 12 may be “folded” into a container that is much smaller than the assembled carrier assembly 10 with modules 16, such as for storage and shipment. Thereafter the carrier 12 may be easily unfolded or removed from the container at its installation site, such as in a manner similar to a “rope ladder” or set of Christmas tree lights.

Referring back to FIG. 1, any desired number of carriers 12 may be included in any desired configuration. In the embodiment shown, two identical opposing carriers 13, 14 are used. A first carrier 13 is shown engaged with a first end 18a of each illustrated module 16, while a second carrier 14 is shown engaged with the second (opposite) end 18b of each of the modules 16.

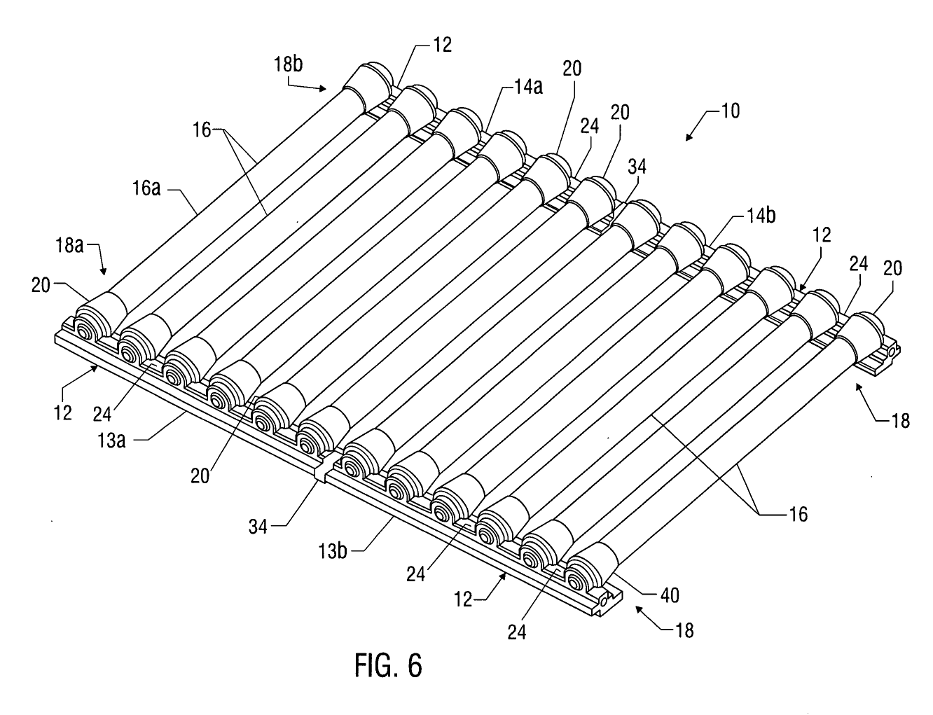

In other embodiments, two or more adjacent carriers 12 may be included, such as to increase photovoltaic energy collection of the carrier assembly 10, or for any other desired purpose. In FIG. 6, for example, the illustrated carriers 12 are interconnectable lengthwise (along their longitudinal axes), so that multiple carriers 12 may be aligned on either or both sides 18a, 18b of the modules 16. Each aligned set of carrier 13a, 13b and carriers 14a, 14b of this embodiment are interconnected with the use of a clip 34, respectively. However, any other suitable components or techniques may be used for interconnecting the carriers 12, such as by interlocking, matable or snapping engagement, friction fitting, screws or other connectors.

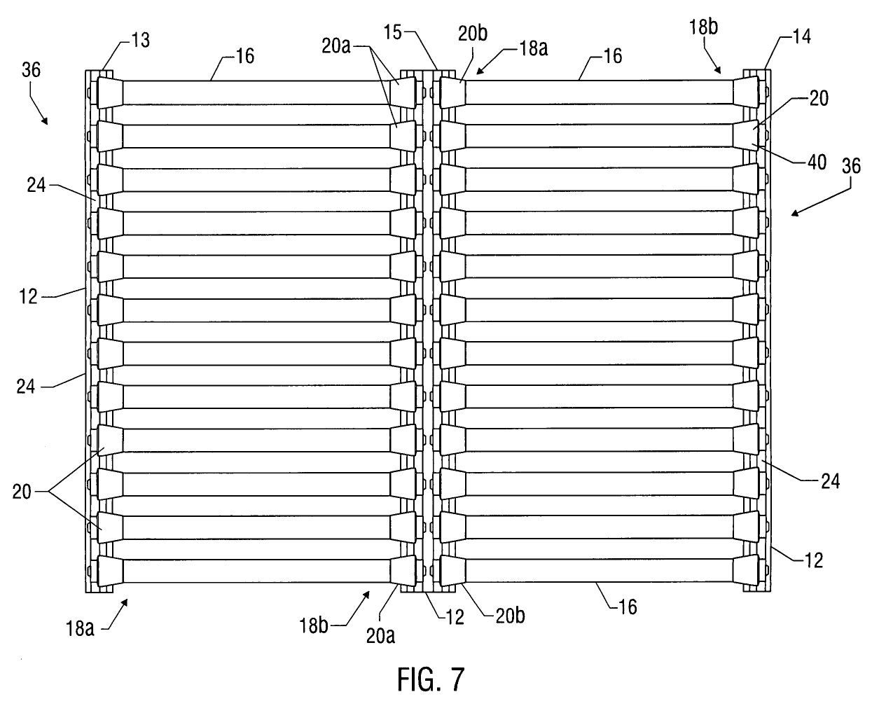

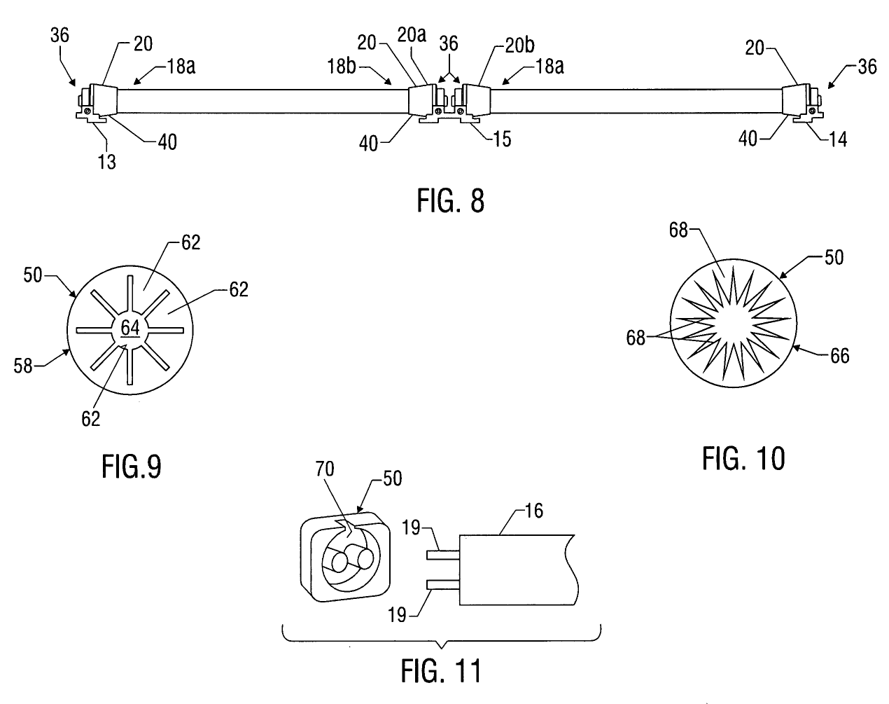

For another example, the carrier assembly 10 of FIG. 7 is capable of holding two rows of modules 16 side-by-side with the use of first, second and middle carriers 13, 14, 15. As shown in FIG. 8, the middle carrier 15 includes receptacles 20a, 20b facing in opposite directions. The middle carrier 15 is thus capable of holding the second end 18b of a first set of modules 16 on its left side and the first end 18a of a second set of modules 16 on its right side. In this embodiment, the middle carrier 15 is, like the first and second carriers 13, 14, moveable between adjacent receptacles 20 so that the entire carrier assembly 10 is movable between receptacles 20. However, a side-by-side arrangement may instead be configured with the use of a set of interconnecting back-to-back carriers 12 instead of a middle carrier 15. The back-to-back carriers (not shown) may be interconnectable at their outside surfaces 36 by interlocking, matable or snapping engagement, friction fitting, and/or with screws, clips or other connectors, or any other suitable method. For still another example arrangement of adjacent carriers, multiple carriers 12 may be interconnectable and layered above one another to create a multi-tiered carrier assembly (not shown).

Referring again to FIG. 1, the receptacles 20 may also have any suitable form, construction and configuration, as long as each receptacle 20 is capable of engaging at least one module 16. In some embodiments, the carrier 12 may be designed with receptacles 20 capable of engaging multiple modules 16. In the embodiment of FIG. 1, each receptacle 20 engages a single module 16. As shown in FIG. 3, the illustrated receptacle 20 includes a shell portion 40 that surrounds a cavity, or opening, 42 within which an end 18 of a module 16 is insertable and removable. In this example, the shell portion 40 is capable of grippingly engaging the outside surface 16a of the module 16 to assist in holding the module(s) 16 in the cavity 42. For example, the shell portion 40 may be shaped to assist in gripping the module 16, such as with a cone-like shape, and/or constructed of a gripping material, such as rubber. However, the shell portion 40 need not be designed or configured to assist in holding the module 16.

The receptacles 20 may be arranged in any desired configuration. In the embodiment of FIG. 1, for example, numerous receptacles 20 are aligned in a single row in spaced relationship along at least part of the length of each carrier 13, 14. However, as few as two receptacles 20 may be included in a carrier 12. For another example, multiple rows (not shown) of receptacles 20 may be provided on a carrier 12. If desired, the multiple rows of receptacles 20 may be located at differing heights on the carrier 20 with adjacent receptacles on adjacent rows staggered relative to one another, such as for optimal light absorption, or any other desired purpose.

Referring again to FIG. 3, the carrier 12 may also be capable of electrically connecting the module(s) 16 engaged in its receptacles 20. When included, any suitable components and techniques may be used for electrically connecting the carrier 12 to the engaged module(s) 16. In the embodiment shown, the carrier 12 includes at least one electrically conductive line (ECL) 44 that electrically connects the modules 16 disposed in its various receptacles 20. As used herein and in the appended claims, the term “electrically conductive line” and variations thereof means any material(s) or component(s) capable of electrically joining at least two elongated photovoltaic modules.

The electrically conductive line 44 may have any suitable construction and configuration. For example, the ECL 44 may be a metal ribbon or strip, or a series thereof. For another example, the ECL 44 may include a series of electrically conducting wires, strips or other members. In the embodiment of FIGS. 1 and 3, the ECL 44 is a bus-type connection line that includes a thin, flexible, metallic wire 46 coated with plastic, such as for flexibility and durability. The ECL 44 in the first carrier 13 connects all the (anode) output contacts 19 of the modules 16 to a common anode terminal (not shown), such as a commercially available male or female electrical plug or receptacle. Similarly, the ECL 44 in the second carrier 14 connects all the (cathode) output contacts 19 to a common cathode terminal (not shown). The illustrated modules 16 are thus connected in parallel. In this manner, the electrical connection between the modules 16 of this example is defined by two bus-like connections in the carrier assembly 10. For another example, the modules 16 may be arranged so that they are connected in series (not shown).

The ECL 44 may electrically connect the modules 16 in any desired manner. For example, the ECL 44 may be soldered directly (not shown) to the output contacts 19 of the modules 16. In the embodiment of FIG. 1, the ECL 44 extends through the length of the carrier 12 (including the bridge portions 24) and electrically connects to an output contact connector 50 (e.g. FIG. 3) disposed within the carrier 12 at each receptacle 20 and which engages the output contact 19 of the module 16 therein.

The ECL 44 and connectors 50 may be electrically connected together and disposed within the carrier 12 in any suitable manner. For example, the ECL 44 and connectors 50 may be formed integrally in a single unit, connected by solder, interlocking, matable or snapping engagement, friction fitting, or with the use of one or more connector, such as a clip. In the embodiment of FIG. 3, the ECL 44 and connectors 50 are connected by spot weld and embedded in the carrier 12. For example, the ECL 44 and connectors 50 may be placed into a mold form used for fabricating the carrier 12, wherein rubber or a rubber composite is thereafter injected or extruded. In some embodiments, the ECL 44 is disposed in a passageway 48 in the carrier 12. If desired, the passageway 48 may be wider than the ECL 44 to allow flexing of the ECL 44 and assist in protecting the ECL 44 from breakage or disconnection.

When included, the connector 50 may have any suitable form and construction and may electrically connect with the module(s) 16 in any desired manner. In the example of in FIG. 3, the illustrated connector 50 is an electrically conductive, deformable leaf member 58 embedded in the carrier 12. The leaf member 58 includes numerous leaves 62 (e.g. FIG. 9) that crimp or deform into engagement with an output contact 19 of the module 16 when the output contact 19 of the module 16 is pressingly engaged with or pushed into an opening 64 of the leaf member 58.

For another example, in FIG. 10, the connector 50 is an electrically conductive, deformable gripper 66 with saw teeth 68 that crimp or deform onto the output contact 19 of a module 16. For yet another example, in FIG. 11, the connector 50 includes a passage 70 (akin to a typical overhead fluorescent light fixture receptacle) within which one or more output contact 19 of a module 16 is twisted into locking engagement. In even further examples, the connector (not shown) may be designed for screwing, press fit, snapping or mating engagement with one or more output contact 19.

If desired, in addition to providing an electrical connection with one or more module 16, the connector 50 may assist in mechanically engaging, or holding, the module 16 in the receptacle 20. For example, each of the connectors 50 of FIGS. 1-11 is capable of releasably gripping an output contact 10 of a module 16, thus assisting in holding the module 16 in the receptacle 20 of a carrier 12.

Other examples and details of ECL's and connectors which may, in certain instances, be used with the carrier assembly 10 of the present disclosure and details of their construction and operation may be described in U.S. patent application Ser. Nos. 11/378,835, 60/859,213, 60/859,212, 60/859,188, 60/859,033, 60/859,215, 60/861,162, 60/901,517, 61/001,605, 60/994,696 and all U.S. patent applications and patents claiming priority thereto, all of which have a common assignee as the present application and are hereby incorporated by reference herein in their entireties.

Accordingly, in some embodiments, the present disclosure involves an apparatus for retaining at least two elongated photovoltaic modules and includes at least first and second carriers. The first carrier includes at least first and second adjacent receptacles, each receptacle being engageable with a first end of at least one elongated photovoltaic module. The second carrier also includes at least first and second adjacent receptacles, each receptacle being engageable with a second end of at least one elongated photovoltaic module. The first and second carriers are each movable between its respective first and second receptacles. When the first carrier is engaged with the first end and the second carrier is engaged with the second end of at least two elongated photovoltaic modules, the apparatus is capable of retaining the first and second carriers and the carriers are concurrently moveable between elongated photovoltaic modules.

In various embodiments, each carrier includes at least one electrically conductive line capable of electrically connecting the elongated photovoltaic modules engaged with it. There are also embodiments of the present disclosure that involve a flexible carrier useful in a carrier assembly capable of retaining a plurality of elongated photovoltaic modules. The carrier includes a plurality of receptacles, bridge portions and output contact connectors, and at least one electrically conductive line. Each receptacle is releasably engageable with at least one elongated photovoltaic module. Each bridge portion is disposed between adjacent receptacles and is moveable sufficient to enable the position or relationship of one adjacent receptacle to be changed relative the other adjacent receptacle so that the carrier is moveable between adjacent receptacles. At least one output contact connector is associated with each receptacle. Each output contact connector is electrically connectable with at least one output contact of at least one elongated photovoltaic module. The electrically conductive line is capable of electrically connecting the output contact connectors.

In some embodiments, the present disclosure involves an apparatus for producing electric energy. The apparatus includes at least two elongated photovoltaic modules and at least first and second module carriers. Each elongated photovoltaic module includes an active photovoltaic device and a protective structure surrounding the photovoltaic device. The photovoltaic device includes a rigid substrate, a back electrode disposed on the rigid substrate, a photovoltaic layer (operable to produce an electric potential and electric current) disposed on the back electrode and a transparent conductive oxide disposed on the photovoltaic layer.

The first and second module carriers are coupled to first and second ends of each module, respectively. Each carrier includes at least two receptacles and a bridge portion disposed therebetween. The first receptacle of each carrier is operable to engage an end of a first module and includes an electrical connection to the first module. The second receptacle of each carrier is operable to engage an end of a second module and includes an electrical connection to the second module. The bridge portion electrically couples the first and second modules. Each of the first and second receptacles and bridge portion includes an outer surface constructed at least partially of non-conductive material and the bridge portion is bendable when subjected to the force of gravity.

Many embodiments of the present disclosure involve a method of manufacturing a flexible carrier capable of engaging and electrically connecting a plurality of elongated photovoltaic modules. The method includes forming a mold for the carrier that has portions for holding a plurality of longitudinally aligned output contact connectors so that each output contact connector is capable of electrically connecting with at least one elongated photovoltaic module that may be engaged with the carrier. The mold also includes at least one portion for holding at least one electrically conductive line that extends along the longitudinal axis of the carrier and electrically connects the output contact connectors. At least one electrically conductive line and a plurality of output contact connectors are placed into the mold. A molten non-electrically conductive, flexible material is placed into the mold. When the non-electrically conductive, flexible material cools, it retains the electrically conductive line(s) and output contact connectors in their desired positions and is bendable between adjacent output contact connectors.

Accordingly, the present disclosure includes features and advantages which are believed to enable it to advance photovoltaic energy absorption or collection technology including characteristics and advantages described above and in the appended claims and/or shown in the accompanying drawings, and additional features and benefits apparent to those skilled in the art upon consideration of this patent. However, each of the appended claims does not require each of the components and acts described above or shown in the drawings and is in no way limited to the above-described examples and methods of assembly and operation. Any one or more of such components, features and processes may be employed in any suitable configuration without inclusion of other such components, features and processes. Moreover, the present disclosure includes additional features, capabilities, functions, methods, uses and applications that have not been specifically addressed herein but are, or will become, apparent from the description herein, the appended drawings and claims.

The methods described above and which may be claimed herein and any other methods which may fall within the scope of the appended claims can be performed in any desired suitable order and are not necessarily limited to the sequence described herein or as may be listed in any appended claims. Further, the methods of the present disclosure do not necessarily require use of the particular examples shown and described in the present specification, but are equally applicable with any other suitable structure, form and configuration of components.

While examples have been shown and described, many variations, modifications and/or changes of the system, apparatus and methods herein, such as in the components, details of construction and operation, arrangement of parts and/or methods of use, are possible, contemplated by the patent applicant(s), within the scope of the appended claims, and may be made and used by one of ordinary skill in the art without departing from the spirit or teachings of this disclosure and scope of the appended claims. Thus, all matter herein set forth or shown in the accompanying drawings should be interpreted as illustrative, and the scope of this disclosure and the appended claims should not be limited to the examples described and shown herein.

1. An apparatus for retaining at least two elongated photovoltaic modules, each elongated photovoltaic module including first and second ends, the apparatus comprising:
at least first and second carriers,
said first carrier including at least first and second adjacent receptacles, each said receptacle being engageable with a first respective end of at least one elongated photovoltaic module, said first carrier being moveable between said at least first and second receptacles, and
said second carrier including at least first and second adjacent receptacles, each said receptacle being engageable with a second respective end of at least one elongated photovoltaic module, said second carrier being movable between said at least first and second receptacles,
wherein when said first carrier is engaged with the first respective end and said second carrier is engaged with the second respective end of at least two elongated photovoltaic modules, the apparatus is capable of retaining the at least two elongated photovoltaic modules and said first and second carriers are concurrently moveable between the at least two elongated photovoltaic modules.

2. The apparatus of claim 1 wherein said first carrier is bendable between said at least first and second receptacles of said first carrier, and said second carrier is bendable between said at least first and second receptacles of said second carrier.

3. The apparatus of claim 2 wherein each of said first and second carriers includes a plurality of adjacent receptacles and is bendable between said adjacent receptacles, respectively.

4. The apparatus of claim 3 wherein each said carrier includes a bridge portion disposed between each adjacent said receptacle, each said bridge portion being at least partially constructed of flexible, non-electrically conductive material.

5. The apparatus of claim 4 wherein each said bridge portion is constructed of at least one among plastic and rubber.

6. The apparatus of claim 2 wherein each said carrier includes at least one electrically conductive line capable of electrically connecting the elongated photovoltaic modules engaged therewith.

7. The apparatus of claim 6 wherein each elongated photovoltaic module includes at least one electrical output contact at each of its first and second ends, wherein each said carrier includes a plurality of output contact connectors, each said output contact connector being electrically connectable with at least one output contact of at least one elongated photovoltaic module and at least one said electrically conductive line.

8. The apparatus of claim 7 wherein each said output contact connector is at least one among a saw-tooth member and a leaf member, each said saw-tooth member and leaf member being electrically connectable and mechanically engageable with at least one output contact of at least one elongated photovoltaic module.

9. The apparatus of claim 7 wherein each said receptacle is constructed of non-electrically conductive material and includes a shell portion capable of grippingly engaging at least one elongated photovoltaic module proximate to one of its ends.

10. The apparatus of claim 1 wherein each said first and second carrier includes at least one hinged portion disposed between said respective at least first and second adjacent receptacles, each said hinged portion capable of allowing said respective carrier to be moveable between said at least first and second adjacent receptacles.

11. The apparatus of claim 10 wherein each said carrier includes at least one electrically conductive line capable of electrically connecting the elongated photovoltaic modules engaged therewith.

12. The apparatus of claim 11 wherein each elongated photovoltaic module includes at least one electrical output contact at each of its first and second ends, wherein each said carrier includes a plurality of output contact connectors, each said output contact connector being electrically connectable and mechanically engageable with at least one output contact of at least one elongated photovoltaic module and at least one said electrically conductive line.

13. The apparatus of claim 12 wherein each said receptacle is constructed of non-electrically conductive material and includes a shell portion capable of grippingly engaging at least one elongated photovoltaic module proximate to one of its ends.

14. A carrier assembly capable of retaining a plurality of elongated photovoltaic modules, each elongated photovoltaic module including first and second ends, the apparatus comprising:
at least first and second carriers,
said first carrier including a plurality of receptacles, each said receptacle being engageable with a first end of at least one elongated photovoltaic module, said first carrier being moveable between adjacent said receptacles,
said first carrier further including at least one electrically conductive line capable of electrically connecting the elongated photovoltaic modules engaged therewith, and
said second carrier including a plurality of receptacles, each said receptacle being engageable with a second end of at least one elongated photovoltaic module, said second carrier being moveable between adjacent said receptacles,
said second carrier further including at least one electrically conductive line capable of electrically connecting the elongated photovoltaic modules engaged therewith.

15. The apparatus of claim 14 further including a third said carrier, said third carrier including a plurality of receptacles, each said receptacle being engageable with a first end of at least one elongated photovoltaic module, said third carrier being interconnectable with said first carrier along their respective longitudinal axes.

16. The apparatus of claim 14 wherein each said carrier has front and back sides, wherein each said receptacle of each of said first and second carriers is disposed on said front side of said respective carrier, further including a third said carrier, said third carrier including a plurality of receptacles, each said receptacle being engageable with a second end of at least one elongated photovoltaic module, said third carrier being interconnectable with said first carrier at their respective back sides.

17. The apparatus of claim 14 further including a third said carrier, said third carrier including first and second sets of receptacles, said first and second sets of receptacles facing in opposite directions, each of said first set of receptacles engageable with a second end of at least one elongated photovoltaic module, and each of said second set of receptacles engageable with a first end of at least one elongated photovoltaic module.

18. A flexible carrier useful in a carrier assembly capable of retaining a plurality of elongated photovoltaic modules, each elongated photovoltaic module including first and second ends and at least one electrical output contact at each of its first and second ends, the flexible carrier comprising:
a plurality of receptacles, each said receptacle being releasably engageable over an end of at least one elongated photovoltaic module;
a plurality of bridge portions, each said bridge portion being disposed between adjacent said receptacles, each said bridge portion being moveable sufficient to enable the position or relationship of one said adjacent receptacles to be changed relative the other said adjacent receptacle, wherein the flexible carrier is moveable between adjacent said receptacles;
a plurality of output contact connectors, at least one said output contact connector being associated with each said receptacle, each said output contact connector being electrically connectable with at least one output contact of at least one elongated photovoltaic module; and
at least one electrically conductive line capable of electrically connecting said plurality of output contact connectors.

19. The flexible carrier of claim 18 wherein all of said receptacles are disposed in a single row and face the same direction.

20. The flexible carrier of claim 18 wherein at least some of said plurality of receptacles are staggered between the top and bottom of the flexible carrier relative to at least one adjacent said receptacle.

21. The flexible carrier of claim 18 wherein some of said plurality of receptacles face the opposite direction relative to other of said plurality of receptacles.

22. The flexible carrier of claim 18 wherein each said bridge portion is constructed at least partially of a flexible, non-electrically conductive material.

23. The flexible carrier of claim 18 wherein each said bridge portion includes at least one hinged portion.

24. An apparatus for producing electric energy, the apparatus comprising:
at least two elongated photovoltaic modules, each said elongated photovoltaic module having a first end and a second end, each said elongated photovoltaic module comprising
an active photovoltaic device comprising
a rigid substrate,
a back electrode disposed on said rigid substrate,
a photovoltaic layer disposed on said back electrode, said photovoltaic layer operable to produce an electric potential and electric current, and
a transparent conductive oxide disposed on said photovoltaic layer, and
a protective structure surrounding said active photovoltaic device;
a first module carrier coupled to said first end of each of said at least two elongated photovoltaic modules; and
a second module carrier coupled to said second end of each of said at least two elongated photovoltaic modules,
said first and the second module carriers each comprising
a first receptacle operable to engage an end of a first said elongated photovoltaic module, said first receptacle including an electrical connection to said first elongated photovoltaic module,
a second receptacle operable to engage an end of a second said elongated photovoltaic module, said second receptacle including an electrical connection to said second elongated photovoltaic module, and
a bridge portion disposed between said first and second receptacles, wherein said bridge portion electrically couples said first and second elongated photovoltaic modules,
each of said first and second receptacles and said bridge portion including an outer surface constructed at least partially of non-conductive material, wherein said bridge portion is bendable when subjected to the force of gravity.

25. A method of manufacturing a flexible carrier capable of engaging and electrically connecting a plurality of elongated photovoltaic modules, the method comprising:
forming a mold for the flexible carrier, the mold including portions for holding a plurality of longitudinally aligned output contact connectors so that each output contact connector is capable of electrically connecting with at least one elongated photovoltaic module that may be engaged with the flexible carrier, and at least one portion for holding at least one electrically conductive line that extends along the longitudinal axis of the flexible carrier and electrically connects the output contact connectors;
placing at least one electrically conductive line and a plurality of output contact connectors into the mold; and
placing a molten non-electrically conductive, flexible material into the mold, whereby when the non-electrically conductive, flexible material cools, it retains the at least one electrically conductive line and plurality of output contact connectors in their desired positions and is movable between adjacent output contact connectors.
